(19) United States
(12) Patent Application Publication
(10) Pub. No.: US 2015/0041205 A1
(43) Pub. Date: Feb. 12, 2015

(54) THIN PACKAGE STRUCTURE WITH ENHANCED STRENGTH

(71) Applicant: KINSUS INTERCONNECT TECHNOLOGY CORP., Taoyuan (TW)

(72) Inventors: Hsueh-Ping Chien, Taoyuan County (TW); Jun-Chung Hsu, Taoyuan County (TW)

(73) Assignee: KINSUS INTERCONNECT TECHNOLOGY CORP., Taoyuan (TW)

(21) Appl. No.: 13/960,159

(22) Filed: Aug. 6, 2013

(51) Int. Cl. H05K 1/11

(52) U.S. Cl. CPC H05K 1/113
USPC 174/264

(57) ABSTRACT

A thin package structure with enhanced strength includes a support carrier plate and a thin circuit board. The thin circuit board is formed on the support carrier plate and includes a first circuit layer, a dielectric layer and a second circuit layer. The first circuit layer includes the first circuit patterns and the first connection pads. The dielectric layer covers the first circuit layer. The second circuit layer is formed on or embedded in an upper surface of the dielectric layer and includes the second circuit patterns and the second connection pads. Connection plugs are formed in the dielectric layer to connect the first and second connection pads. The support carrier plate provides mechanical strength to avoid warping or deforming. It is feasible to direct test the package structure without disassembling so as to improve the convenience in testing.

### BACKGROUND OF THE INVENTION

1. Field of the Invention

The present invention generally relates to a thin package structure, and more specifically to a thin package structure with enhanced strength provided by a support carrier plate, which is formed with a plurality of openings to facilitate testing.

2. The Prior Arts

Please refer to FIG. 1, a cross sectional view showing the thin package structure in the prior arts. As shown in FIG. 1, the traditional thin package structure 100 generally includes the first circuit layer 20, the dielectric layer 25, the second circuit layer 30, the first solder mask 41 and the second solder mask 43. The first circuit layer 20 is embedded into a lower surface of the dielectric layer 25, and includes a plurality of first circuit patterns 21 and a plurality of first connection pads 23. The first circuit patterns 21 and the first connection pads 23 are connected to each other (not visible). The second circuit layer 30 is formed on an upper surface of the dielectric layer 25, and includes a plurality of second circuit patterns 31 and a plurality of second connection pads 33. The second circuit patterns 31 and the second connection pads 33 are connected to each other (not visible). A plurality of holes are formed in the dielectric layer 25, and further are filled to form the connection plugs 27, each connected to the corresponding first connection pad 23 and second connection pad 33 such that the first circuit patterns 21 and the second circuit patterns 31 are electrically connected relative to one another.

The first solder mask 41 is formed on the lower surface of the dielectric layer 20, and covers the first circuit patterns 21 and part of the first connection pads 23. The second solder mask 43 is formed on the upper surface of the dielectric layer 20, and covers the second circuit patterns 31 and part of the second connection pads 33.

However, it is still needed to perform additional processes, such as treatment, testing. Since the thickness of the thin package structure 100 is less than 300 μm, it is easy to warp or deform during the processes of treatment, test, or transportation between different treatments and/or tests. As a result, the conveyer carrying the thin package structure 100 is possibly stuck and fails, or the circuit is loosen and drops to cause serious damage to the final products. Therefore, it is greatly needed to provide a new package structure with enhanced strength to overcome the drawbacks in the prior arts.

### SUMMARY OF THE INVENTION

The primary objective of the present invention is to provide a thin package structure with enhanced strength. The thin package structure of the present invention includes a support carrier plate and a thin circuit board. The thin circuit board is formed on the support carrier plate and at least includes a first circuit layer, a dielectric layer and a second circuit layer. The first circuit layer is formed on an upper surface of the support carrier plate and includes a plurality of first circuit patterns and a plurality of first connection pads. The first circuit patterns and the first connection pads are connected to each other. The dielectric layer is formed on the upper surface of the support carrier plate to cover the first circuit layer and has a plurality of holes. The second circuit layer is formed on or embedded in an upper surface of the dielectric layer and includes a plurality of second circuit patterns and a plurality of second connection pads. The second circuit patterns and the second connection pads are connected to each other. A plurality of connection plugs are formed in the holes of the dielectric layer, and each connection plug is connected to the corresponding first and second connection pads.

A plurality of openings are formed on the support carrier plate, and each opening corresponds to the first connection pad. The support carrier plate provides mechanical strength to avoid warping or deforming in the processes of manufacturing, test and transportation. Furthermore, because of the openings provided on the support carrier plate, it is feasible to direct test the package structure without disassembling so as to improve the convenience in testing.

### BRIEF DESCRIPTION OF THE DRAWINGS

The present invention can be understood in more detail by reading the subsequent detailed description in conjunction with the examples and references made to the accompanying drawings, wherein:

FIG. 1 is a cross sectional view showing a thin package structure in the prior arts;

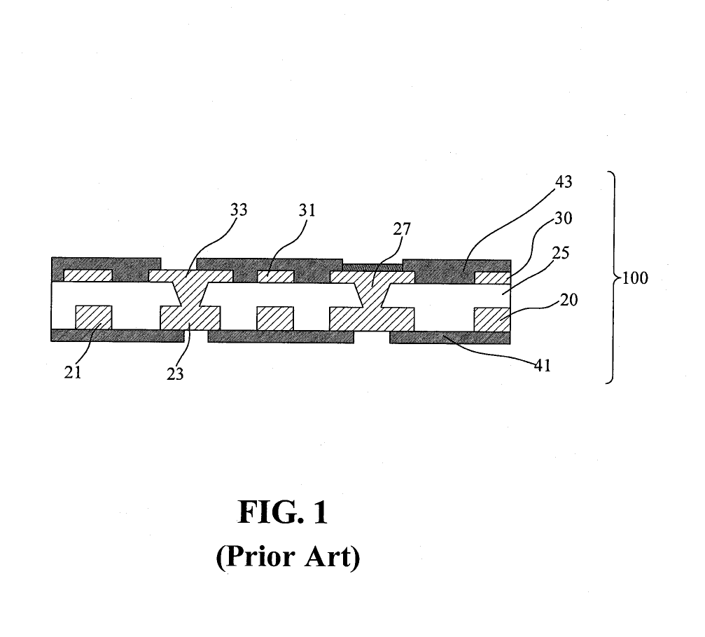

FIG. 2A is a cross sectional view showing the first embodiment of a thin package structure with enhanced strength according to the present invention;

FIG. 2B is a cross sectional view showing the second embodiment of the thin package structure with enhanced strength according to the present invention; and

FIG. 2C is a cross sectional view showing the third embodiment of the thin package structure with enhanced strength according to the present invention.

### DETAILED DESCRIPTION OF THE PREFERRED EMBODIMENTS

The present invention may be embodied in various forms and the details of the preferred embodiments of the present invention will be described in the subsequent content with reference to the accompanying drawings. The drawings (not to scale) show and depict only the preferred embodiments of the invention and shall not be considered as limitations to the scope of the present invention. Modifications of the shape of the present invention shall too be considered to be within the spirit of the present invention.

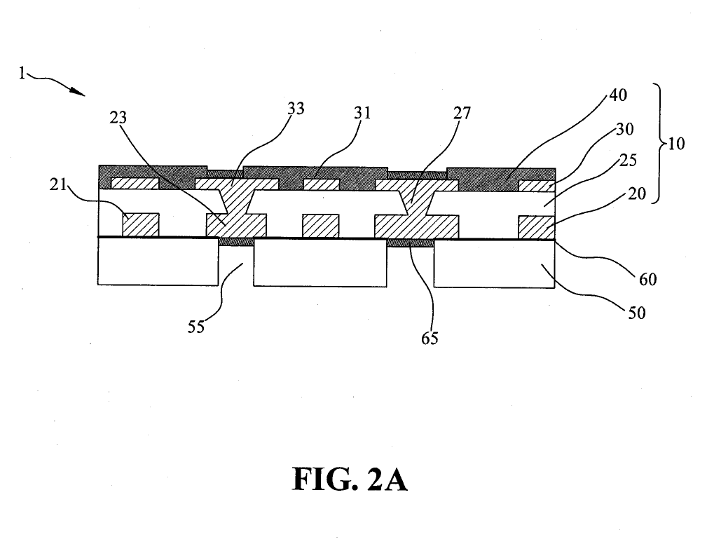

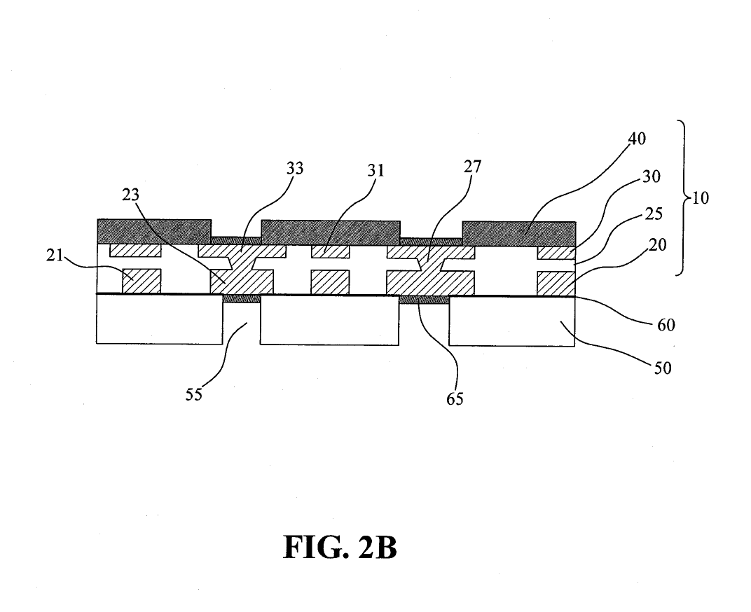

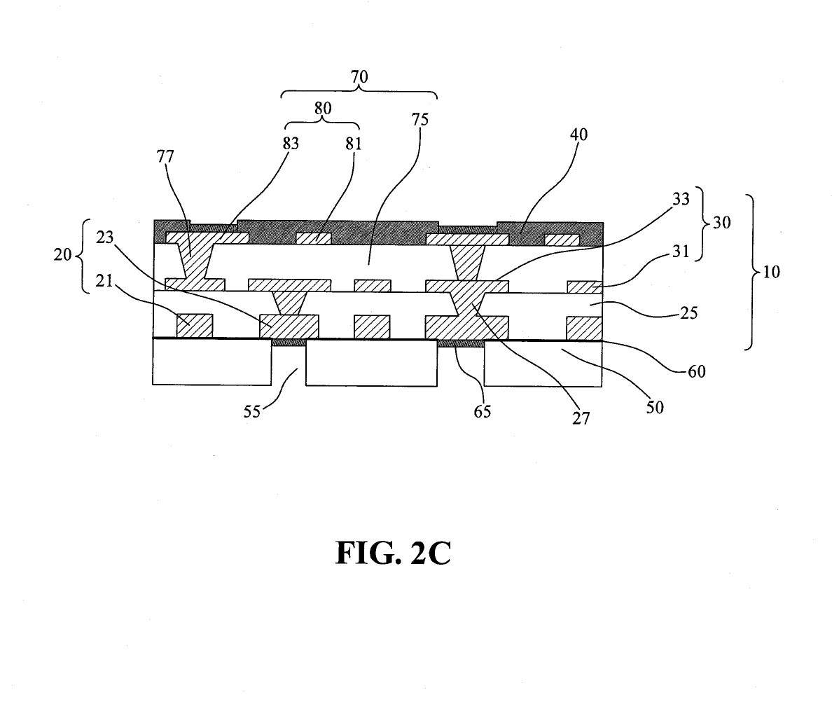

FIG. 2A shows a cross sectional view illustrating the first embodiment of a thin package structure with enhanced strength according to the present invention. As shown in FIG. 2A, the thin package structure 1 of the present embodiment includes a thin circuit board 10 and a support carrier plate 50. Specifically, the thin circuit board 10 is formed on the support carrier plate 50, and includes at least a first circuit layer 20, a dielectric layer 25, a second circuit layer 30 and a solder mask 40. The first circuit layer 20 is formed on an upper surface of the support carrier plate 50. Furthermore, the first circuit layer 20 includes a plurality of first circuit patterns 21 and a plurality of first connection pads 23, and the first circuit patterns 21 and the first connection pads 23 are connected to each other (not visible). The dielectric layer 25 is formed on the upper surface of the support carrier plate 50 to cover the first circuit layer 20, and includes a plurality of second circuit patterns 31 and a plurality of second connection pads 33. The second circuit patterns 31 and the second connection pads 33 are connected to each other (not visible). The dielectric layer 25 has a plurality of holes, in which and a plurality of connection plugs 27 are formed. Each connection plug 27 is connected to the corresponding first and second connection pads 23 and 33. Therefore, the first circuit layer 20 and the second circuit layer 30 are electrically connected.

The thin circuit board 10 has a thickness less than 300 um. A solder mask 40 is formed on the upper surface of the dielectric layer 25, and covers the second circuit patterns 31 and part of the second connection pads 33. A plurality of openings 55 are formed on the support carrier plate 50, each opening 55 corresponding to the first connection pad 23. Moreover, an electroplating seed layer 60 is formed between the upper surface of the support carrier plate 50 and the first circuit layer 20. A surface treatment layer 65 is formed on the upper surface of the first connection pads 23 exposed to the openings 55, and the second connection pads 33 not covered by the solder mask 40.

FIG. 2B shows a cross sectional view of the second embodiment of the thin package structure with enhanced strength according to the present invention. As shown in FIG. 2B, the second embodiment is substantially similar to the first embodiment in structure. The primary difference is that the second circuit layer 30 in the second embodiment is embedded in the upper surface of the dielectric layer 25. Other components are the same, and the description thereof is omitted.

Additionally, FIG. 2C shows a cross sectional view of the third embodiment of the thin package structure with enhanced strength according to the present invention. As shown in FIG. 2C, the third embodiment is substantially modified from the first embodiment. More specifically, at least one stacked structure 70 is further formed on the dielectric layer 25 and the second circuit layer 30. Each stacked structure 70 includes a second dielectric layer 75 and a third circuit layer 80 provided on the upper surface of the second dielectric layer 75. The third circuit layer 80 includes a plurality of third circuit patterns 81 and a plurality of third connection pads 83. The circuit third patterns 81 and the third connection pads 83 are connected to each other. Particularly, in one lowest stacked structure 70, the lower surface of the second dielectric layer 75 is connected to the upper surface of the dielectric layer 25, and covers the second circuit layer 30. The second connection pads 33 and the third connection pads 85 are connected via a plurality of second connection plugs 77 formed in a plurality of holes of the second dielectric layer 75.

Additionally, in other stacked structures 70, the lower surface of the second dielectric layer 75 is connected to the upper surface of another dielectric layer 75. The third connection pads 83 in the upper stacked structure 70 are connected to the third connection pads of lower adjacent stacked structure 70 via the second connection pads 77. In an uppermost stacked structure 70, a solder mask 40 is provided on the upper surface of the second dielectric layer 75, and covers the third circuit patterns 81 and part of the third connection pads 83. Furthermore, the surface treatment layer 65 is formed on the third connection pads 83, which is not covered by the solder mask 40.

One feature of the present invention is that the support carrier plate 50 provides mechanical strength to prevent the thin circuit board 10 from warping or deforming in the processes of manufacturing, test and transportation. Meanwhile the openings 55 are provided on the support carrier plate 50 so as to enable to direct test without disassembling. Therefore, the convenience in testing is greatly improved.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A thin package structure with enhanced strength, comprising:
a support carrier plate; and
a thin circuit board formed on the support carrier plate, and including at least a first circuit layer formed on an upper surface of the support carrier plate, a dielectric layer and a second circuit layer, wherein the first circuit layer includes a plurality of first circuit patterns and a plurality of first connection pads, the first circuit patterns and the first connection pads are connected to each other, the dielectric layer is formed on the upper surface of the support carrier plate to cover the first circuit layer and has a plurality of holes, the second circuit layer is formed on or embedded in an upper surface of the dielectric layer and includes a plurality of second circuit patterns and a plurality of second connection pads, the second circuit patterns and the second connection pads are connected to each other, a plurality of connection plugs are formed in the holes of the dielectric layer, each connection plug is connected to the corresponding first and second connection pads, and a plurality of openings are formed on the support carrier plate, each opening corresponding to the first connection pad.

2. The thin package structure as claimed in claim 1, wherein the thin circuit board has a thickness less than 300 μm.

3. The thin package structure as claimed in claim 1, wherein the thin circuit board further includes a solder mask formed on the upper surface of the dielectric layer, and covers the second circuit patterns and part of the second connection pads.

4. The thin package structure as claimed in claim 1, further comprising at least one stacked structure on the dielectric layer and the second circuit layer, wherein each stacked structure includes a second dielectric layer and a third circuit layer, the third circuit layer is provided on an upper surface of the second dielectric layer and includes a plurality of circuit patterns and a plurality of third connection pads, the circuit patterns and the third connection pads are connected to each other,
wherein in a lowest stacked structure, a lower surface of the second dielectric layer is connected to the upper surface of the dielectric layer and covers the second circuit layer, the second connection pads and the third connection pads are connected via a plurality of second connection plugs formed in a plurality of holes of the second dielectric layer,
wherein in other stacked structures, the lower surface of the second dielectric layer is connected to an upper surface of another dielectric layer, the third connection pads are connected to the third connection pads of another stacked structure via the second connection pads, and
wherein in an uppermost stacked structure, a solder mask is provided on the upper surface of the second dielectric layer and covers the third circuit patterns and part of the third connection pads.

5. The thin package structure as claimed in claim 1, further comprising an electroplating seed layer formed between the upper surface of the support carrier plate and the first circuit layer.

6. The thin package structure as claimed in claim 1, further comprising a surface treatment layer formed on the upper surface of the first connection pads exposed to the openings.

7. The thin package structure as claimed in claim 3, further comprising a surface treatment layer formed on the second connection pads not covered by the solder mask.

8. The thin package structure as claimed in claim 4, further comprising a surface treatment layer formed on the third connection pads not covered by the solder mask.
